(19) United States
(12) Patent Application Publication
(10) Pub. No.: US 2024/0097079 A1
(43) Pub. Date: Mar. 21, 2024

(54) IC PACKAGE WITH LEDS

(71) Applicant: Intel Corporation, Santa Clara, CA (US)

(72) Inventors: Brandon C. MARIN, Gilbert, AZ (US); Khaled AHMED, San Jose, CA (US); Srinivas V. PIETAMBARAM, Chandler, AZ (US); Hiroki TANAKA, Gilbert, AZ (US); Paul WEST, Portland, OR (US); Kristof DARMAWIKARTA, Chandler, AZ (US); Gang DUAN, Chandler, AZ (US); Jeremy D. ECTON, Gilbert, AZ (US); Suddhasattwa NAD, Chandler, AZ (US)

(21) Appl. No.: 17/949,857

(22) Filed: Sep. 21, 2022

(51) Int. Cl. H01L 33/48; H01L 25/075; H01L 33/00; H01L 33/32; H01L 33/62

(52) U.S. Cl. CPC H01L 33/486; H01L 25/0753; H01L 33/0075; H01L 33/32; H01L 33/62; H01L 2933/0066

(57) ABSTRACT

Integrated circuit (IC) packages are disclosed. In some embodiments, an IC package includes a glass substrate, a micro light emitting diode (LED), a semiconductor die, one or more through glass vias (TGVs) and a package substrate. The micro LED is positioned over the glass substrate. The TGVs are integrated into the glass substrate and connect the micro LED to the semiconductor die. The semiconductor die is connected to the package substrate to receive external signals when connected to a motherboard.

### BACKGROUND

Bandwidth specification for the interchange input and output (I/O) exchange of external signals with integrated circuit (IC) package has been steadily doubling every two years. Packaging and I/O technologies need to scale to meet this bandwidth demand. As a result, package pin counts and I/O data rates continue to increase. However, electrical I/O reach (length of electrical printed circuit board (PCB) trace or cable) continues to reduce at increased data rates. I/O bandwidth capabilities are thus an important characteristic of IC packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an embodiment of an integrated circuit (IC) package 100, in accordance with some embodiments.

FIG. 2 illustrates an embodiment of an IC package 200, in accordance with some embodiments.

FIG. 3 illustrates an embodiment of an IC package 300, in accordance with some embodiments.

FIG. 4A-4B illustrate an embodiment of a micro light emitting diode (LED), in accordance with some embodiments.

FIG. 5A-FIG. 5K illustrate a method of manufacturing an IC package, in accordance with some embodiments.

FIG. 6 is a flow diagram 600 that describes a method of manufacturing an IC package, in accordance with some embodiments.

FIG. 7 is an electronic device having a display, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

(Optional, use when applicable) Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

Embodiments of an IC package are disclosed. In some embodiments, the IC package includes a glass substrate where micro light emitting diodes (LEDs) are formed on the glass substrate itself rather than being transferred from a silicon substrate. One or more through glass vias (TGVs) are used to connect the micro LEDs to a semiconductor die. A package substrate is used to transfer signals from a motherboard to the semiconductor die. By forming the micro LEDs on the glass substrate and by using TGVs, the cost of manufacturing the micro LEDs and the complexity required to connect the micro LEDs to the semiconductor die is decreased, in accordance with some embodiments. The decrease in complexity increases the I/O bandwidth of the IC package, in accordance with some embodiments.

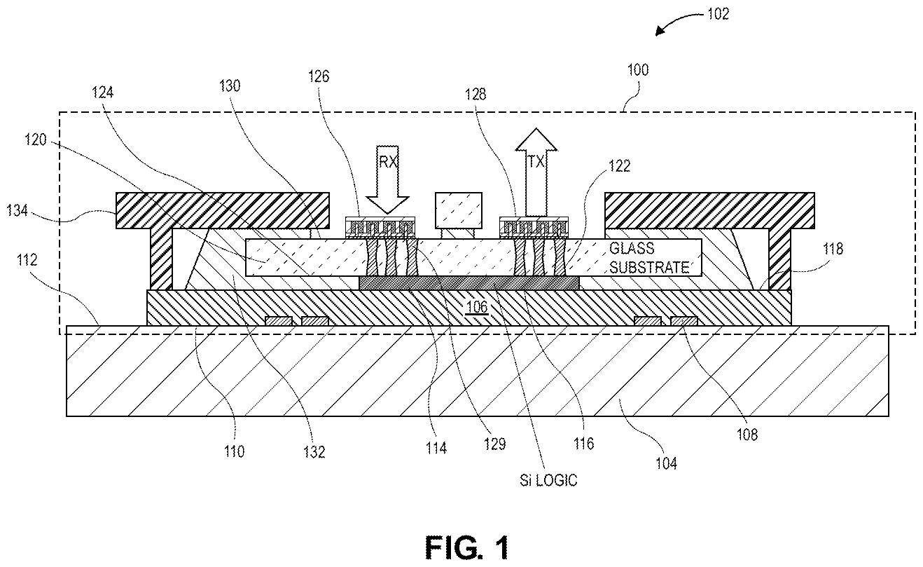

FIG. 1 is an embodiment of an integrated circuit (IC) package 100, in accordance with some embodiments.

In FIG. 1, the IC package 100 is part of a computer system 102 and is thus connected to a motherboard 104. The IC package 100 includes a package substrate 106. In some embodiments, the package substrate 106 is formed from a polymer or ceramic. In this embodiment, conductive pads 108 are formed on a surface 110 of the package substrate 106 to connect the package substrate 106 to the motherboard 104. In this manner, input and output signals are transmitted into and out of the package substrate 106. The surface 110 of the package substrate 106 is on a surface 112 of the motherboard 104.

A semiconductor die 114 is connected to the package substrate 106 to receive and transmit input and output signals to and from the package substrate 106. A surface 116 of the semiconductor die 114 is on and over a surface 118 of the package substrate 106. The surface 118 of the package substrate 106 is opposite to the surface 110 of the package substrate 106. The package substrate 106 includes conductive traces (not explicitly shown) and conductive vias (not explicitly shown, that transmit signals within the package substrate 106.

The IC package 100 further includes a glass substrate 120. A surface 122 of the semiconductor die 114 is positioned on and under a surface 124 of the glass substrate 120. The surface 122 of the semiconductor die 114 is opposite the surface 116 of the semiconductor die 114. A micro light emitting diode (LED) 126 and a micro LED 128 are positioned on and over a surface 130 of the glass substrate 120. In this embodiment, two micro LEDs 126, 128 are shown in the IC package 100. In some embodiments, the IC package 100 has 16 micro LEDs similar to micro LEDs 126, 128. In other embodiments, the IC package 100 has any number of micro LEDs equal to or greater than 1. The surface 130 of the glass substrate 120 is opposite the surface 124 of the glass substrate 120.

In FIG. 1, the micro LED 126 and the micro LED 128 are each exposed through the IC package 100. The micro LED 126 is configured to operate as a detector LED. Thus, the micro LED 126 is configured to detect wireless light signals at the appropriate frequency ranges and generate and/or manipulate electrical signals in response to the wireless light signals. The micro LED 126 is electrically connected to the semiconductor die 114 by the TGVs 129. Thus, electrical signals generated by the micro LED 126 are transmitted to the semiconductor die 114 by the TGVs 129. In some embodiments, the semiconductor die 114 includes processing logic that processes the electrical signals from the micro LED 126. For example, the electrical signals from the micro LED 126 may represent bits carried by the light detected by the micro LED 126. The semiconductor die 114 may include combinational logic that processes the bits.

The micro LED 128 operates as an emitter LED. The micro LED 128 is connected to the semiconductor die 114 through the TGVs 129. The micro LED 128 receives electrical signals from the semiconductor die 114 through the TGVs 129 and, in response, generates light signals that are emitted from the micro LED 128. For example, the semiconductor die 114 may include combinational logic generates the electrical signal such that they represent output bits. The electrical signals may then be sent to the micro LED 128 such that the light signals generated by the micro LED 128 are modulated with the output bits.

In this embodiment, the glass substrate 120 is encased in a molding 132. However, the molding 132 does not encase portions of the glass substrate 120 with the micro LEDs 126, 128 so that the micro LEDs 126, 128 are exposed through the IC package 100. Furthermore, the IC package 100 includes a casing 134. The casing 134 includes vertical walls that are supported on the package substrate 106 and horizontal walls at the top of the IC package 100 that are supported by the vertical walls and the molding 132. However, the horizontal walls include apertures so that the micro LEDs 126, 128 are exposed through the IC package 100.

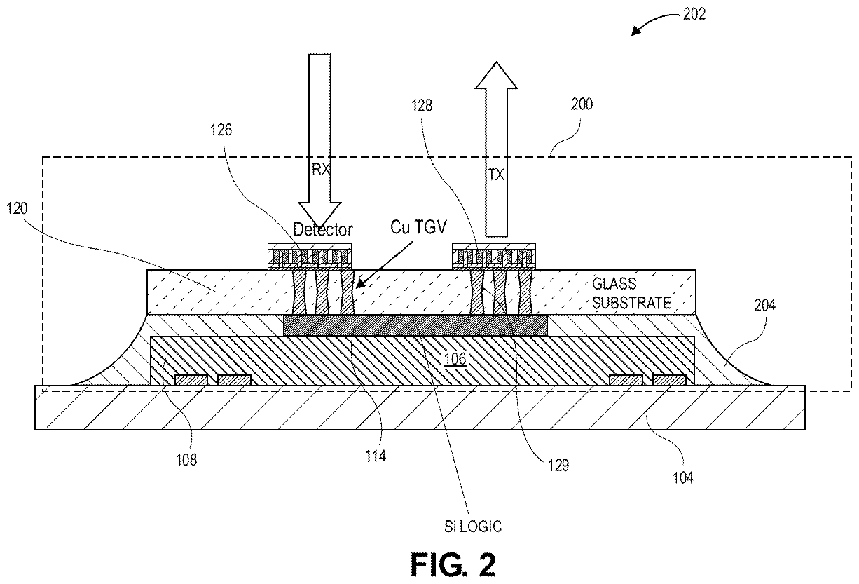

FIG. 2 illustrates an embodiment of an IC package 200, in accordance with some embodiments.

The IC package 200 is part of a computer system 202 and thus is connected to the motherboard 104. The IC package 200 also includes the package substrate 106, the semiconductor die 114, the glass substrate 120, the TGVs 129, the micro LED 126, and the micro LED 128 discussed above with respect to FIG. 1. However, in this embodiments, the IC package 200 includes molding 204 and does not include an encasing. In this embodiment, the molding 204 only encapsulates the semiconductor die 114 and the package substrate 106 but does not encapsulate the glass substrate 120.

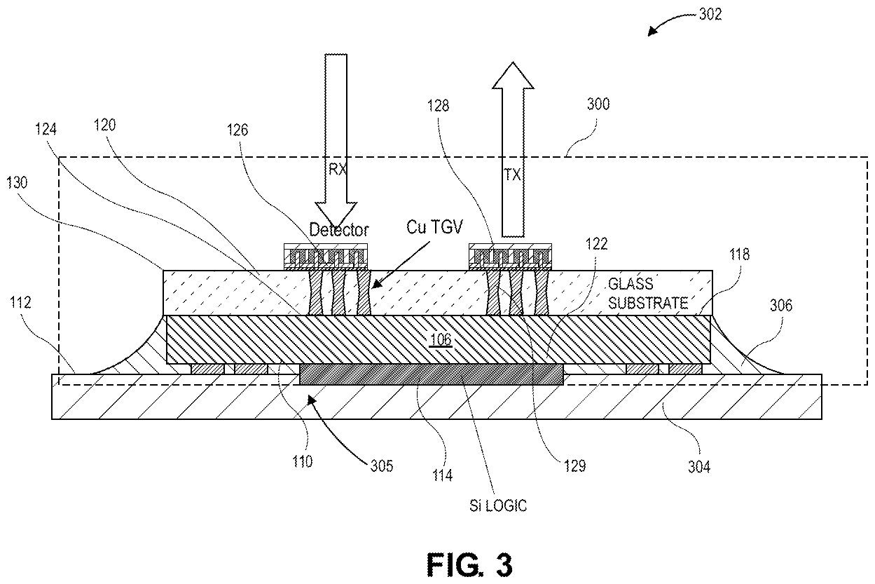

FIG. 3 illustrates an embodiment of an IC package 300, in accordance with some embodiments.

The IC package 300 is part of a computer system 302 and thus is connected to the motherboard 304. However, in this embodiment, the motherboard defines a cavity 305.

The IC package 300 includes the package substrate 106, the semiconductor die 114, the glass substrate 120, the TGVs 129, the micro LED 126, and the micro LED 128 except that these components are not connected in the same manner discussed above with respect to FIG. 1. Instead, the surface 122 of the semiconductor die 114 is positioned on and under the surface 110 of the package substrate 106. The semiconductor die 114 is connected to the package substrate 106 such that electric signal are input and output from the semiconductor die 114 through the package substrate 106.

The surface 118 of the package substrate 106 is positioned under and on the surface 124 of the glass substrate 120. In this manner, TGVs 129 connect to the package substrate 106. The micro LED 126 and the micro LED 128 are connected to the TGVs 129 and are positioned on and over the surface 130 of the glass substrate 120. Thus, electrical signals are received and transmitted by the micro LEDs 126, 128 through the TGVs 129. In this embodiment, electric signals to and from the semiconductor die 114 pass through conductors of the package substrate 106, through the TGVs 129, then to or from the micro LEDs 126, 128.

In FIG. 3, the semiconductor die 114 is positioned within the cavity 305 of the motherboard 304 when the IC package 300 is connected to the motherboard 304. This protects and electromagnetically isolates the semiconductor die 114. A molding 306 encapsulates the package substrate 106.

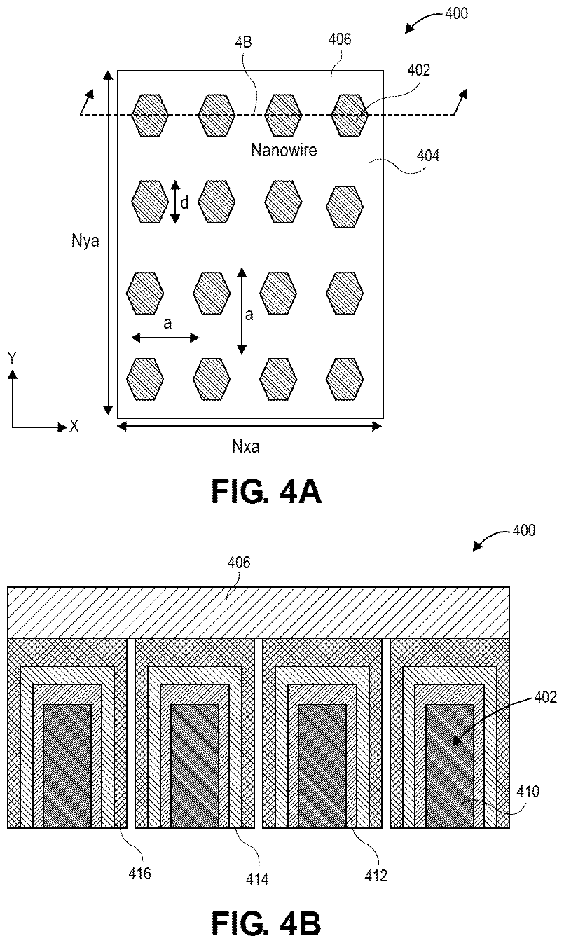

FIG. 4A is a bottom view of one embodiment of a micro LED 400, in accordance with some embodiments.

The micro LED 400 is an example of the micro LED 126 in FIG. 1-FIG. 3, in accordance with some embodiments. The micro LED 400 is an example of the micro LED 128 in FIG. 1.

In FIG. 4, 16 nanowires 402 are shown formed on a surface 404 an electrode 406. In FIG. 4A, an X-axis is defined and a Y-axis that is orthogonal to the X-axis is defined. There are four rows (parallel to the X-axis) and four columns (parallel to the Y-axis) of nanowires 402. Each row of nanowires 402 includes four nanowires 402 and each column of nanowires includes four nanowires 402. Other embodiments of the micro LED 400 includes any number of nanowires equal to or greater than 1. Each of the nanowires 402 in each row of nanowires is evenly spaced apart and aligned. Each of the nanowires 402 in each column of nanowires is evenly spaced apart and aligned.

Each of the nanowires 402 has a diameter of distance d, where d is a range from 0.5-50 um in accordance with some embodiments. With respect to each row of nanowires 402, the nanowires are spaced apart by a distance a in each row. With respect to each column of nanowires 402, the nanowires 402 are spaced apart by a distance a in each column, where a is a range from 0.5-100 um in accordance with some embodiments. In other embodiments, the spacing between the nanowires 402 in each row of nanowires 402 and the spacing between the nanowires 402 in each column of the nanowires 402 is different. In this embodiment, the nanowires 402 have a cross section (in the plane of the X-axis and the Y-axis) that is a hexagonal. However, the nanowires 402 may have a cross section (in the plane of the X-axis and the Y-axis) of any suitable shape. For example, in some embodiments, the nanowires 402 have a cross sectional shape (in the plane of the X-axis and the Y-axis) of a cross. In some embodiments, the nanowires 402 have a circular cross sectional shape (in the plane of the X-axis and the Y-axis).

In FIG. 4A, the electrode 406 has a cross sectional shape (in the plane of the X-axis and the Y-axis) that is a quadrilateral. In other embodiments, the electrode 406 has a cross sectional shape (in the plane of the X-axis and the Y-axis) that is any suitable shape. Opposing and parallel sides of the electrode 406 are parallel to the X-axis. A length of these sides is Nxa, where d is a range from 0.5-500 um in accordance with some embodiments. Opposing and parallel sides of the electrode 406 are parallel to the Y-axis. A length of these sides is Nya, where Nya is a range from 0.5-500 um in accordance with some embodiments.

FIG. 4B is a cross sectional view of the micro LED 400 shown in FIG. 4A along a cross sectional line 4B, in accordance with some embodiments.

The micro LED 400 illustrates 4 nanowires 402 along a row of the nanowires 402 (See FIG. 4A). As shown in FIG. 4A, there are 4 nanowires 402 along each column such that the micro LED 400 includes a 4×4 matrix of nanowires 402. However, in other embodiments, any sized matrix may be provided in the micro LED 400. Furthermore, in some embodiments, the micro LED 400 may have no columns and just a single row or no rows and just a single column. The number of nanowires 402 per micro LED 400 is at least one. In some embodiments, each of the nanowires 402 may be configured to emit the same color in the micro LED 400. In some embodiments, each or at least some of the nanowires 402 emit the different colors in the micro LED 400.

In FIG. 4B, each of the nanowires 402 includes a nanowire core 410. In some embodiments, the nanowire cores 410 are formed from a glass. In this manner, the nanowire cores 410 are more easily attach to a glass substrate (See glass substrate 120 in FIG. 1-FIG. 3). In some embodiments, the nanowire cores 410 are formed from a silicon oxide (e.g., SiO, SiO₂, SiO₃) that is in a glass solid state.

In each nanowire 402, various gallium nitride (GaN) layers 412, 414, 416 are deposited over the nanowire cores 410. In FIG. 4, n-type indium gallium nitride (InGaN) shells 412 are grown around the nanowire cores 410, e.g., using by metal organic chemical vapor deposition (MOCVD). The amount of indium in the n-type InGaN shells 412 depends on the diameter of the nanowire core 410. In an embodiment, smaller core diameters result in the growth of n-type InGaN shells 412 with less indium content. Larger core diameters result in the growth of n-type InGaN shells 412 with greater indium content. In some embodiments, for blue (B) color emission, the indium content is approximately 20%. In some embodiments, for green (G) color emission, the indium content is approximately 30%. In some embodiments, for red (R) color emission, the indium content is approximately 40%. A p-type GaN cladding layer 414 is deposited around the n-type InGaN shells 412, e.g., using MOCVD. The p-type GaN cladding layer 414 are covered by InGaN/GaN multi quantum well shell 416. The electrode 406 is then deposited over the InGaN/GaN multi quantum well shell 416. In some embodiments, the electrode 406 is formed from a p-type GaN and is a transparent metal electrode (ITO).

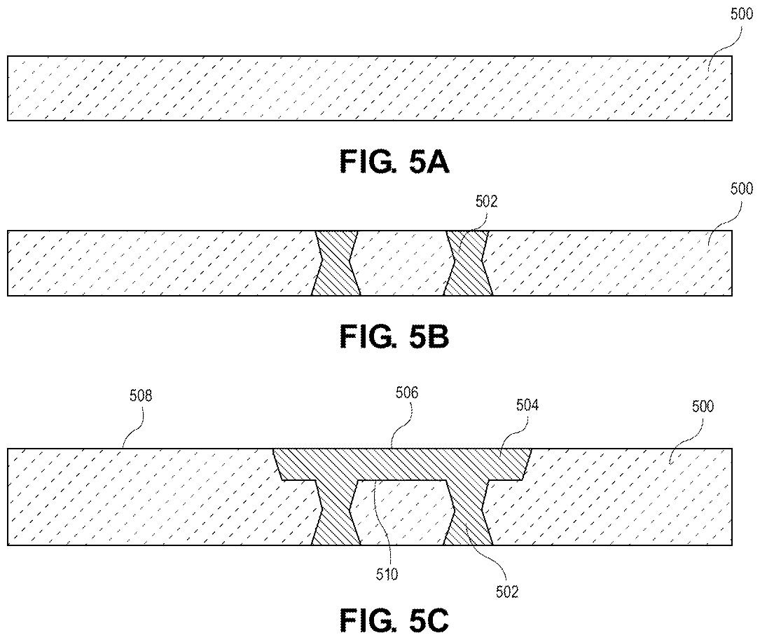

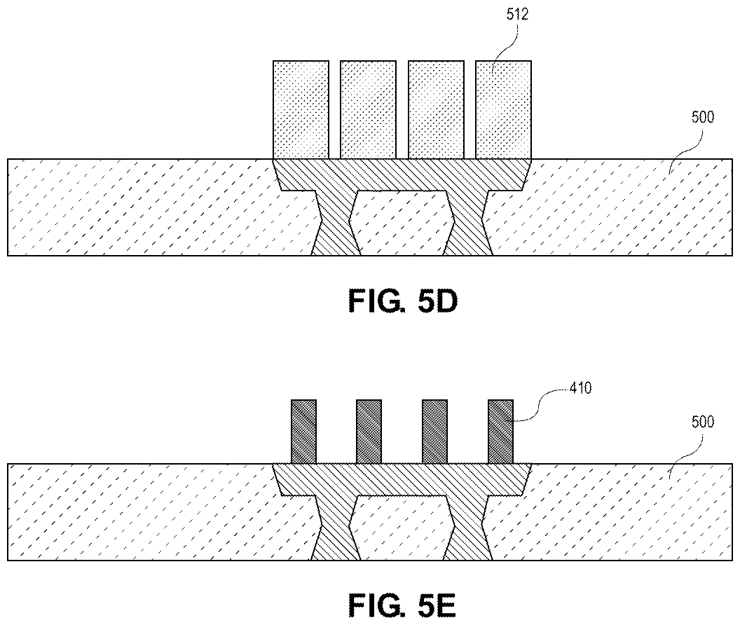

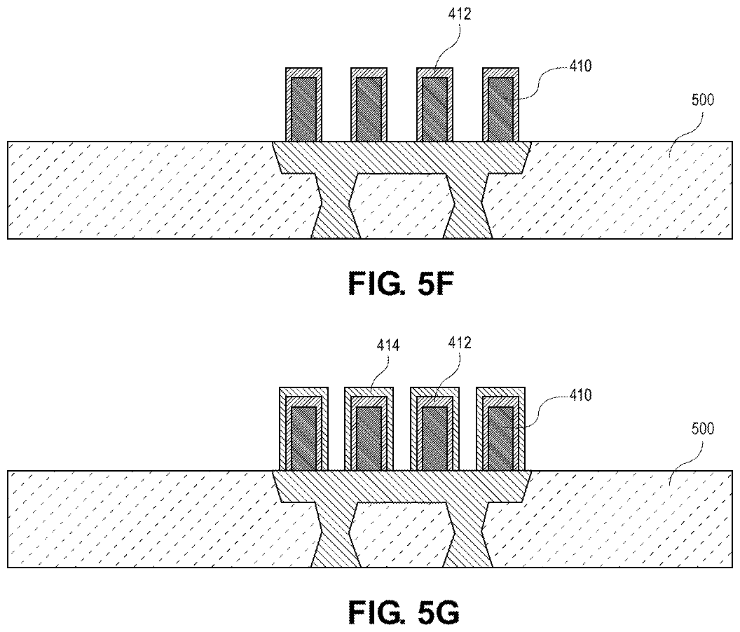

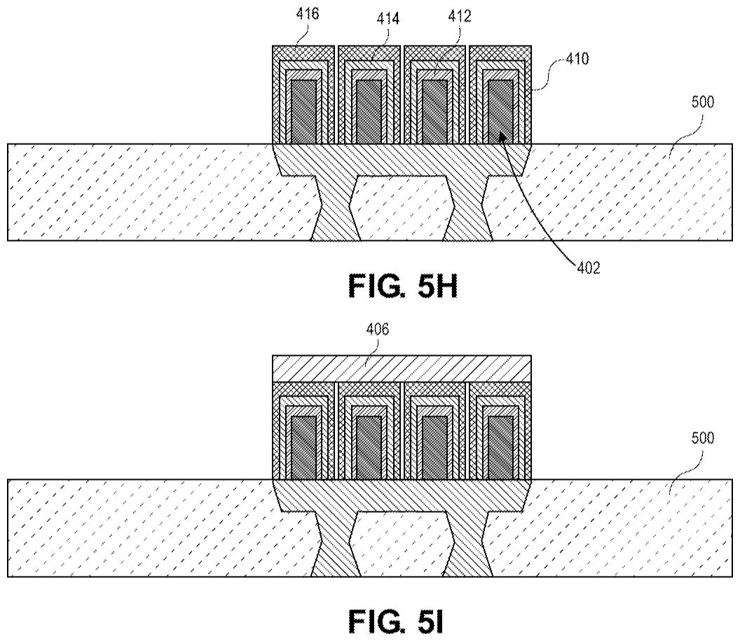

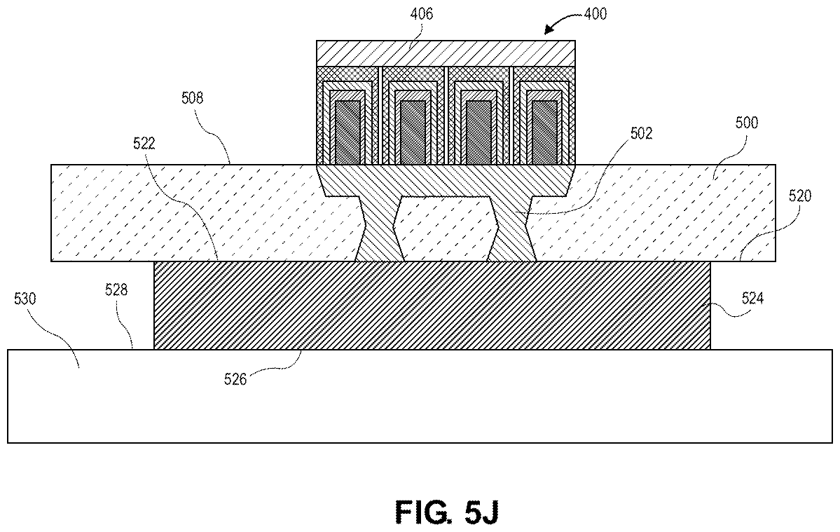

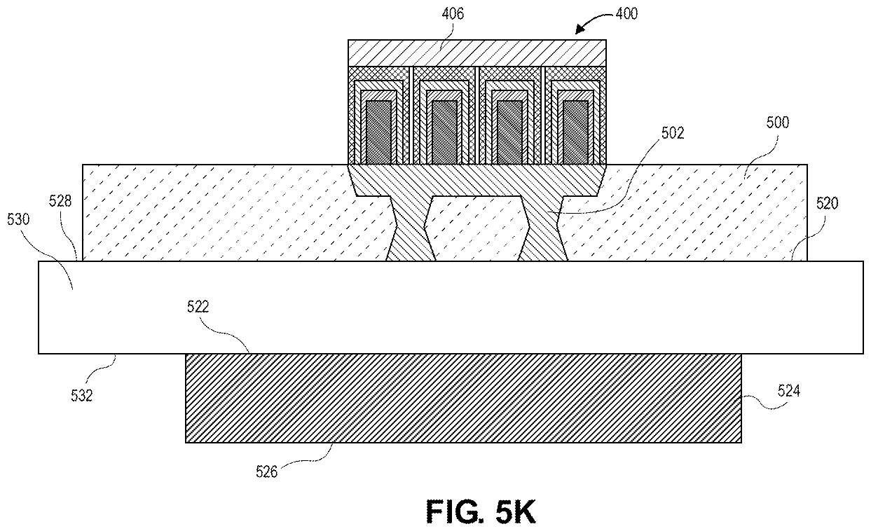

FIG. 5A-FIG. 5K illustrate a method of manufacturing an IC package, in accordance with some embodiments.

FIG. 5A-FIG. 5I are relevant to IC packages 100, 200, 300 in FIG. 1, FIG. 2, and FIG. 3 respectively. FIG. 5J is relevant to the IC package 100 in FIG. 1 and the IC package 200 in FIG. 2. FIG. 5K is relevant to the IC package 300 in FIG. 3.

As shown in FIG. 5A, a glass substrate 500 is provided. The glass substrate 500 may be made or obtained. In some embodiments, non-limiting examples of materials that form the body of the glass substrate 500 include, but are not limited to, silica borate glass, silica carbide or quartz. Glass substrate 500 is an example of glass substrate 120 in FIG. 1, FIG. 2, and FIG. 3, in accordance with some embodiments.

In FIG. 5B, TGVs 502 are formed in the glass substrate 500. In some embodiments, the glass substrate 500 is etched through glass lithography to build cavities, which are then filled with a conductive material such as a metal (e.g., copper) to form the TGVs 502.

In FIG. 5C, a conductive electrode 504 is formed so that a surface 506 of the conductive electrode 504 is exposed through a surface 508 of the glass substrate 500. The conductive electrode 504 makes contact with the TGVs 502 at a surface 510 of the conductive electrode 504. The surface 510 is opposite the surface 506. The conductive electrode 504 is formed by etching the glass substrate 500 and grinding the TGVs 502 to form a cavity that is then electroplated with the conductive material to form the conductive electrode 504. The TGVs 502 are embedded in the glass substrate 500. The conductive electrode 504 is embedded in the glass substrate 500, except that the surface 506 is exposed at the surface 508 of the glass substrate 500.

In FIG. 5D, silicon oxide cores 512 are then formed on and over the surface 506 of the conductive electrode 504. To form the silicon oxide cores 512, a layer of silicon oxide (e.g., SiO, SiO₂, SiO₃) is deposited over the surface 508 and the surface 506. The silicon oxide layer is then etched to form the silicon oxide cores 512.

At FIG. 5E, the silicon oxide cores 512 are converted into a glass solid state to form the nanowire cores 410.

At FIG. 5F, n-type InGaN shells 412 are grown around the nanowire cores 410 using MOCVD. In some embodiments, an n-type InGaN layer is grown over the nanowire cores 410 and then etched to form the individual n-type InGaN shells 412 around the nanowire cores 410.

At FIG. 5G, a p-type GaN cladding layer 414 is deposited around the n-type InGaN shells 412 using MOCVD. In some embodiments, a p-type GaN cladding layer 414 is grown over the InGaN shells 412 and then etched to form the individual p-type GaN cladding layers 414 around the InGaN shells 412.

At FIG. 5H, an InGaN/GaN multi quantum well shell 416 is deposited around the p-type GaN cladding layers 414 using MOCVD. In some embodiments, an InGaN/GaN layer is grown over the p-type GaN cladding layers 414 and then etched to form the InGaN/GaN multi quantum well shells 416 around the p-type GaN cladding layers 414. In this manner, the nanowires 402 are formed.

At FIG. 5I, the electrode 406 is formed on top of the nanowires 402. In some embodiments, a p-type GaN layer is deposited on top of the InGaN/GaN multi quantum well shells 416 and on top of the surface 508 of the glass substrate 500. The p-type GaN layer is then removed from the surface 508 to provide the electrode 406.

FIG. 5J and FIG. 5K illustrate alternate procedures.

At FIG. 5J, a surface 520 of the glass substrate 500 is positioned on and over a surface 522 of a semiconductor die 524. In this manner, the semiconductor die 524 is connected to the micro LED 400 by the TGVs 502. The surface 520 is opposite the surface 508. A surface 526 of the semiconductor die 524 is positioned on and over a surface 528 of a package substrate 530. The surface 522 is opposite the surface 526. In this manner, the semiconductor die 524 is connected to the package substrate 530. The semiconductor die 524 in FIG. 5J is an example of the semiconductor die 114 in FIG. 1 and FIG. 2, in accordance with some embodiments. The package substrate 530 in FIG. 5J is an example of the package substrate 106 in FIG. 1 and FIG. 2, in accordance with some embodiments. Molding and/or encasements can then be provided such as IC package 100, 200 in FIG. 1 and FIG. 2 respectively.

At FIG. 5K, the surface 528 of the package substrate 530 is positioned on and under the surface 520 of a glass substrate 500. In this manner, the package substrate 530 is connected to the micro LED 400 by the TGVs 502. A surface 532 of the package substrate 530 is positioned on and over the surface 522 of the semiconductor die 524. The surface 532 is opposite the surface 528. In this manner, the semiconductor die 524 is connected to the package substrate 530. The semiconductor die 114 in FIG. 5K is an example of the semiconductor die 114 in FIG. 3, in accordance with some embodiments. The package substrate 530 in FIG. 5K is an example of the package substrate 106 in FIG. 3, in accordance with some embodiments. Molding and/or encasements can then be provided to form an IC package, such as IC package 300 in FIG. 3.

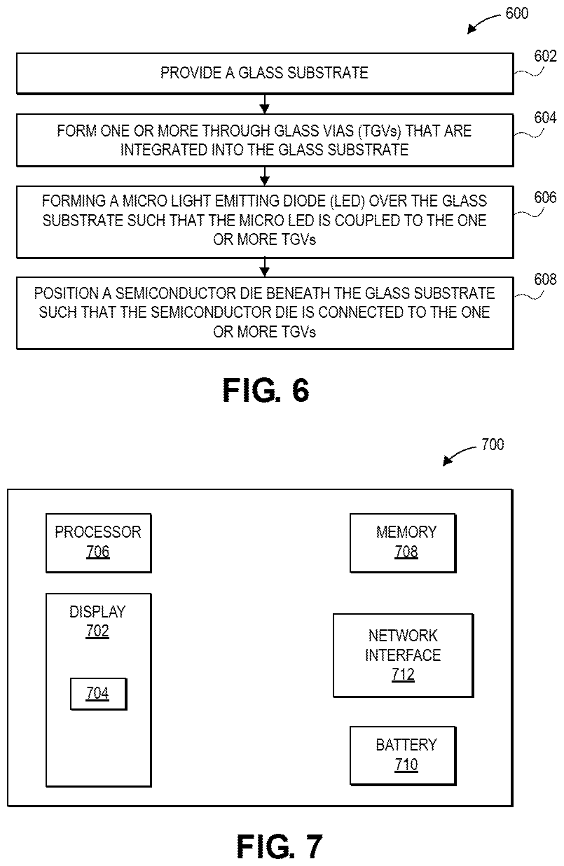

FIG. 6 is a flow diagram 600 that describes a method of manufacturing an IC package, in accordance with some embodiments.

Flow diagram 600 includes block 602-608. Examples of the IC packages that are formed by the flow diagram include IC packages 100, 200, 300 in FIG. 1, FIG. 2, and FIG. 3, respectively. Flow begins at block 602.

At block 602, a glass substrate is provided. An example of the glass substrate includes the glass substrate 120 in FIG. 1-3. Flow then proceeds to block 604.

At block 604, forming one or more TGVs that are integrated into the glass substrate. An example of the TGVs are the TGVs 129 in FIG. 1-FIG. 3. Flow then proceeds to block 606.

At block 606, a micro LED over the glass substrate such that the micro LED is coupled to the one or more TGVs. An example of the micro LED include micro LED 126 and micro LED 128 in FIG. 1-FIG. 3. Flow then proceeds to block 608.

At block 608, a semiconductor die beneath the glass substrate such that the semiconductor die is connected to the one or more TGVs. An example of the semiconductor die is the semiconductor die 114 of FIG. 1-FIG. 3.

FIG. 7 is an electronic device having a display, in accordance with some embodiments.

Referring to FIG. 7, an electronic device 700 has a display or display panel 702 with an IC package 704 that includes micro LEDs (i.e., micro LEDs 126, 128 in FIG. 1-FIG. 3). The display may also have glass layers and other layers, circuitry, and so forth. The display panel 702 may be a micro-LED display panel. As should be apparent, only one IC package 704 is depicted for clarity, though a display panel 702 will have an array or arrays of micro LEDs on one or more IC package 704.

The electronic device 700 may be a mobile device such as smartphone, tablet, notebook, smartwatch, and so forth. The electronic device 700 may be a computing device, stand-alone display, television, display monitor, vehicle computer display, and/or the like. Indeed, the electronic device 700 may generally be any electronic device having a display or display panel.

The electronic device 700 may include a processor 706 (e.g., a central processing unit or CPU) and memory 708. The memory 708 may include volatile memory and nonvolatile memory. The processor 706 or other controller, along with executable code store in the memory 708, may provide for touchscreen control of the display and well as for other features and actions of the electronic device 700.

In addition, the electronic device 700 may include a battery 710 that powers the electronic device including the display panel 702. The electronic device 700 may also include a network interface 712 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 700 may include additional components including circuitry and other components.

Thus, embodiments described herein include micro light-emitting diode (LED) fabrication and assembly.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

Example embodiment 1. An integrated circuit (IC) package, comprising: a glass substrate; a micro light emitting diode (LED) positioned over the glass substrate; a semiconductor die; one or more through glass vias (TGVs), wherein the one or more TGVs are integrated into the glass substrate and the one or more TGVs connect the micro LED to the semiconductor die; a package substrate, wherein the semiconductor die is connected to the package substrate.

Example embodiment 2. The integrated circuit structure of example embodiment 1, where the micro LED comprises: a plurality of nanowire cores positioned over the glass substrate; one or more gallium nitride (GaN) shells positioned over the plurality of nanowire cores.

Example embodiment 3. The integrated circuit structure of example embodiment 2, wherein the plurality of nanocores comprise a silicon oxide in a glass solid state.

Example embodiment 4. The integrated circuit structure of example embodiment 2, wherein the LED further comprises a transparent metal electrode over the one or more GaN shells.

Example embodiment 5. The integrated circuit structure of example embodiment 1, 2, 3, or 4 wherein the semiconductor die includes processing logic.

Example embodiment 6. The integrated circuit structure of example embodiment 1, 2, 3, 4, or 5 wherein the semiconductor die includes components configured to convert light signals from the LED to electric signals for the processing logic.

Example embodiment 7. The integrated circuit structure of example embodiment 1, 2, 3, 4, 5, or 6 wherein the micro LED is a first micro LED and wherein the IC package comprises a second micro LED positioned over the glass substrate, wherein: the second micro LED is connected by the one or more TGVs to the semiconductor die; the first micro LED operates as an emitter LED; and the second micro LED operates as a detector LED.

Example embodiment 8. The integrated circuit structure of example embodiment 1, 2, 3, 4, 5, 6 or 7 further comprising: an insulator formed over the package substrate, wherein the glass substrate is at least partially encased in the insulator.

Example embodiment 9. The integrated circuit structure of example embodiment 1, 2, 3, 4, 5, 6, 7 or 8 further comprising a copper plate, wherein the one or more TGVs and the micro LED are directly on the copper plate and the one or more TGVs directly connect to the copper plate.

Example embodiment 10. The integrated circuit structure of example embodiment 9, wherein the copper plate is at least partially integrated into the glass substrate.

Example embodiment 11. A method of manufacturing an integrated circuit (IC) package, comprising: providing a glass substrate; forming one or more through glass vias (TGVs) that are integrated into the glass substrate; forming a micro light emitting diode (LED) over the glass substrate such that the micro LED is coupled to the one or more TGVs; positioning a semiconductor die beneath the glass substrate such that the semiconductor die is connected to the one or more TGVs.

Example embodiment 12. The method of example embodiment 11, wherein forming the micro LED over the glass substrate comprises: depositing a silicon oxide layer over the glass substrate; etching the silicon oxide layer to form a plurality of silicon oxide cores; converting the silicon oxide cores into a glass solid state to form a plurality of nanowire cores; forming one or more gallium nitride (GaN) shells over the plurality of nanowire cores.

Example embodiment 13. The method of example embodiment 12, wherein the plurality of nanocores are in a tube shape or in a cross-shape.

Example embodiment 14. The method of example embodiment 12 or 13 further comprising forming a transparent metal electrode over the one or more GaN shells.

Example embodiment 15. The method of example embodiment 11, 12, 13, or 14 wherein the semiconductor die includes processing logic.

Example embodiment 16. The method of example embodiment 15, wherein the semiconductor die includes components configured to convert light signals from the LED to electric signals for the processing logic.

Example embodiment 17. The method of example embodiment 11, 12, 13, 14, 15, or 16 wherein the micro LED is first micro LED that operates as an emitter LED, wherein the method further comprises: forming a second micro LED that operates as a detector LED over the glass substrate.

Example embodiment 18. The method of example embodiment 11, 12, 13, 14, 15, 16, or 17 further comprising: forming an insulator over the package substrate such that the glass substrate is at least partially encased in the insulator.

Example embodiment 19. The method of example embodiment 11, 12, 13, 14, 15, 16, 17, or 18 further comprising forming a copper plate, wherein the one or more TGVs and the micro LED is directly on the copper plate and the one or more TGVs directly connect to the copper plate.

Example embodiment 20. The method of example embodiment 19, wherein the copper plate is at least partially integrated into the glass substrate.

What is claimed is:

1. An integrated circuit (IC) package, comprising:
a glass substrate;
a micro light emitting diode (LED) positioned over the glass substrate;
a semiconductor die;
one or more through glass vias (TGVs), wherein the one or more TGVs are integrated into the glass substrate and the one or more TGVs connect the micro LED to the semiconductor die;
a package substrate, wherein the semiconductor die is connected to the package substrate.

2. The IC package of claim 1, the micro LED comprises:
a plurality of nanowire cores positioned over the glass substrate;
one or more gallium nitride (GaN) shells positioned over the plurality of nanowire cores.

3. The IC package of claim 2, wherein the plurality of nanocores comprise a silicon oxide in a glass solid state.

4. The IC package of claim 2, wherein the LED further comprises a transparent metal electrode over the one or more GaN shells.

5. The IC package of claim 1, wherein the semiconductor die includes processing logic.

6. The IC package of claim 5, wherein the semiconductor die includes components configured to convert light signals from the LED to electric signals for the processing logic.

7. The IC package of claim 1, wherein the micro LED is a first micro LED and wherein the IC package comprises a second micro LED positioned over the glass substrate, wherein:
the second micro LED is connected by the one or more TGVs to the semiconductor die;
the first micro LED operates as an emitter LED; and
the second micro LED operates as a detector LED.

8. The IC package of claim 1, further comprising:
an insulator formed over the package substrate, wherein the glass substrate is at least partially encased in the insulator.

9. The IC package of claim 1, further comprising a copper plate, wherein the one or more TGVs and the micro LED are directly on the copper plate and the one or more TGVs directly connect to the copper plate.

10. The IC package of claim 9, wherein the copper plate is at least partially integrated into the glass substrate.

11. A method of manufacturing an integrated circuit (IC) package, comprising:
providing a glass substrate;
forming one or more through glass vias (TGVs) that are integrated into the glass substrate;
forming a micro light emitting diode (LED) over the glass substrate such that the micro LED is coupled to the one or more TGVs;
positioning a semiconductor die beneath the glass substrate such that the semiconductor die is connected to the one or more TGVs.

12. The method of claim 11, wherein forming the micro LED over the glass substrate comprises:
depositing a silicon oxide layer over the glass substrate;
etching the silicon oxide layer to form a plurality of silicon oxide cores;
converting the silicon oxide cores into a glass solid state to form a plurality of nanowire cores;
forming one or more gallium nitride (GaN) shells over the plurality of nanowire cores.

13. The method of claim 12, wherein the plurality of nanocores are in a tube shape or in a cross-shape.

14. The method of claim 12, further comprising forming a transparent metal electrode over the one or more GaN shells.

15. The method of claim 11, wherein the semiconductor die includes processing logic.

16. The method of claim 15, wherein the semiconductor die includes components configured to convert light signals from the micro LED to electric signals for the processing logic.

17. The method of claim 11, wherein the micro LED is first micro LED that operates as an emitter LED, wherein the method further comprises:
forming a second micro LED that operates as a detector LED over the glass substrate.

18. The method of claim 11, further comprising:
forming an insulator over the package substrate such that the glass substrate is at least partially encased in the insulator.

19. The method of claim 11, further comprising forming a copper plate, wherein the one or more TGVs and the micro LED is directly on the copper plate and the one or more TGVs directly connect to the copper plate.

20. The method of claim 19, wherein the copper plate is at least partially integrated into the glass substrate.
